(19) United States
(12) Patent Application Publication
(10) Pub. No.: US 2025/0112621 A1
(43) Pub. Date: Apr. 3, 2025

(54) ACOUSTIC FILTER DEVICE WITH STAGGERED GROUND INDUCTORS

(71) Applicant: Murata Manufacturing Co., Ltd., Nagaokakyo-shi (JP)

(72) Inventors: Santhosh GOTTUPARTHY, Sunnyvale, CA (US); Wei YANG, Goleta, CA (US)

(21) Appl. No.: 18/894,037

(22) Filed: Sep. 24, 2024

Related U.S. Application Data
(60) Provisional application No. 63/586,277, filed on Sep. 28, 2023.

(51) Int. Cl. H03H 9/54; H03H 9/02; H03H 9/17; H03H 9/56

(52) U.S. Cl. CPC H03H 9/542; H03H 9/02228; H03H 9/173; H03H 9/175; H03H 9/564; H03H 9/568

(57) ABSTRACT

A filter device is provided that includes series resonator connected between a pair of ports; shunt resonators connected between a ground connection and a node between one or more of series resonator and one of the pair of ports; and inductors that are connected between the ground connection and the shunt resonators, respectively. The inductors have staggered inductance values that are different from each other. Each of the resonators includes a substrate, a piezoelectric layer attached either directly or via one or more intermediate layers to the substrate, and an interdigital transducer (IDT) on a surface of the piezoelectric layer and that includes interleaved IDT fingers extending from first and second busbars, respectively.

### CROSS REFERENCE TO RELATED APPLICATIONS

The present application claims priority to U.S. Patent Provisional Application No. 63/586,277, filed Sep. 28, 2023, the entire contents of which are hereby incorporated by reference.

### TECHNICAL FIELD

This disclosure relates to radio frequency filters using acoustic wave resonators, and more specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

Currently, RF filters operating at such high frequencies are designed to improve rejections in the stop-band frequencies. As described in more detail below, one technique for doing so is to use a ground inductance in series with a shunt resonator of the RF filter. Providing a tuned inductor with the shunt resonator will create a transmission zero (T_{z}) at a desired frequency to improve rejections. However, such a ground inductor also creates a “flyback” at higher frequencies, which leads to worse wideband rejection. In other words, such RF filters experience flyback, which is a degradation of the filter in higher ranges (e.g., the F_{Range2} range) that consequently reduces the overall performance of these RF filters. According, the acoustic filter devices disclose herein are configured to suppress flyback while still improving the wideband rejection of the frequency response.

Thus, in an exemplary embodiment, a filter device is provided that includes at least one series resonator connected between a pair of ports; a plurality of shunt resonators connected between a ground connection and a node between the at least one series resonator and one of the pair of ports; and a plurality of inductors that are each connected in series between the ground connection and the plurality of shunt resonators, respectively. Moreover, at least two of the plurality of inductors have staggered inductance values that are different from each other. Furthermore, each of the at least one series resonator and the plurality of shunt resonators includes a substrate, a piezoelectric layer attached either directly or via one or more intermediate layers to the substrate, and an interdigital transducer (IDT) on a surface of the piezoelectric layer and including a plurality of interleaved IDT fingers extending from first and second busbars respectively.

In another exemplary aspect of the filter device, the plurality of inductors are connected in parallel to each other.

In another exemplary aspect of the filter device, the at least one series resonator comprises a plurality of series resonators connected in series between the pair of ports. Moreover, each of the plurality of shunt resonators are coupled to a node between a pair of adjacent resonators of the plurality of series resonators or a node between one of the plurality of series resonators and one of the pair of ports.

In another exemplary aspect of the filter device, the piezoelectric layer and the IDT of each of the series and shunt resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved fingers of the IDT.

In another exemplary aspect of the filter device, the substrate of each of the respective resonators includes a base and an intermediate layer and the piezoelectric layer includes a portion that is over a cavity that extends at least partially in the intermediate layer of the substrate. Moreover, the surface of the piezoelectric layer on which the IDT is disposed faces the cavity in an exemplary aspect.

In another exemplary aspect of the filter device, at least one of the at least one series resonator and the plurality of shunt resonators further comprises a Bragg reflector disposed between the substrate and the piezoelectric layer.

In another exemplary aspect of the filter device, each of the plurality of shunt resonators comprises at least two sub-resonators. Moreover, a first sub-resonator of each of the at least two sub-resonators is coupled to an inductor of the plurality of inductors and a second sub-resonator of each of the at least two sub-resonators is coupled directly to the ground connection.

In another exemplary aspect, a filter device is provided that includes at least one series resonator connected between a pair of ports; a plurality of shunt resonators connected between a ground connection and a node between the at least one series resonator and one of the pair of ports; and a plurality of inductors that are each connected in series between the ground connection and the plurality of shunt resonators, respectively. Moreover, at least two of the plurality of inductors have staggered inductance values that are different from each other. Each of the at least one series resonator and the plurality of shunt resonators includes a piezoelectric layer and an interdigital transducer (IDT) on a surface of the piezoelectric layer. In this aspect, the piezoelectric layer and the IDT of each of the series and shunt resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by interleaved fingers of the IDT.

In another exemplary aspect, a radio frequency module is provided that includes a filter device having at least one series resonator connected between a pair of ports, a plurality of shunt resonators connected between a ground connection and a node between the at least one series resonator and one of the pair of ports, and a plurality of inductors that are connected between the ground connection and the plurality of shunt resonators, respectively; and a radio frequency circuit coupled to the filter device, the filter device and the radio frequency circuit being enclosed within a common package. In tis aspect, at least two of the plurality of inductors have staggered inductance values that are different from each other. Moreover, each of the at least one series resonator and the plurality of shunt resonators includes a piezoelectric layer and an interdigital transducer (IDT) on a surface of the piezoelectric layer. In this aspect, the piezoelectric layer and the IDT of each of the respective resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by interleaved fingers of the IDT.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6A is a circuit diagram of a filter using resonators according to an exemplary aspect.

FIG. 6B is an exemplary graph of filter responses of the circuit diagram shown in FIG. 6A according to an exemplary aspect.

FIG. 7A is a circuit diagram of a filter using resonators having a staggered inductor configuration according to an exemplary aspect.

FIG. 7B is an exemplary graph of filter responses of the circuit diagram shown in FIG. 7A according to an exemplary aspect.

FIG. 8A is an exemplary layout of a filter device according to an exemplary aspect.

FIG. 8B an exemplary layout of a filter device having a staggered inductor configuration incorporating exemplary aspects of the present disclosure.

FIG. 8C shows an exemplary graph of filter response implementation of a filter device according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, and a radio frequency module are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

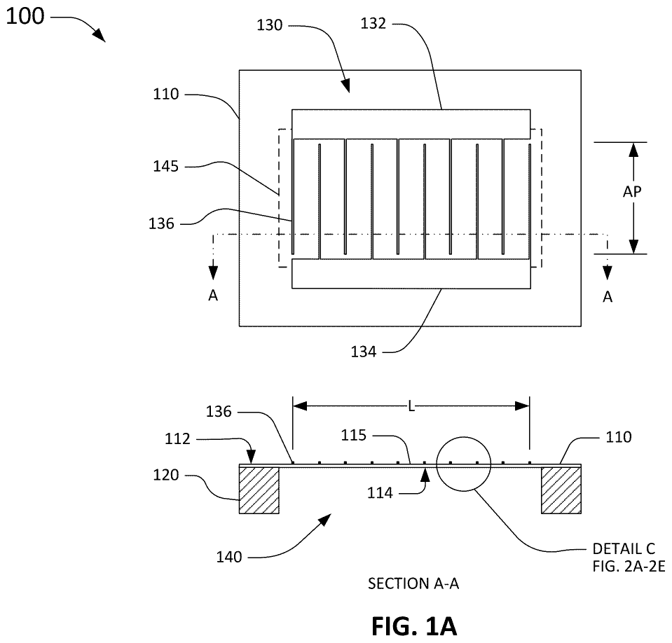

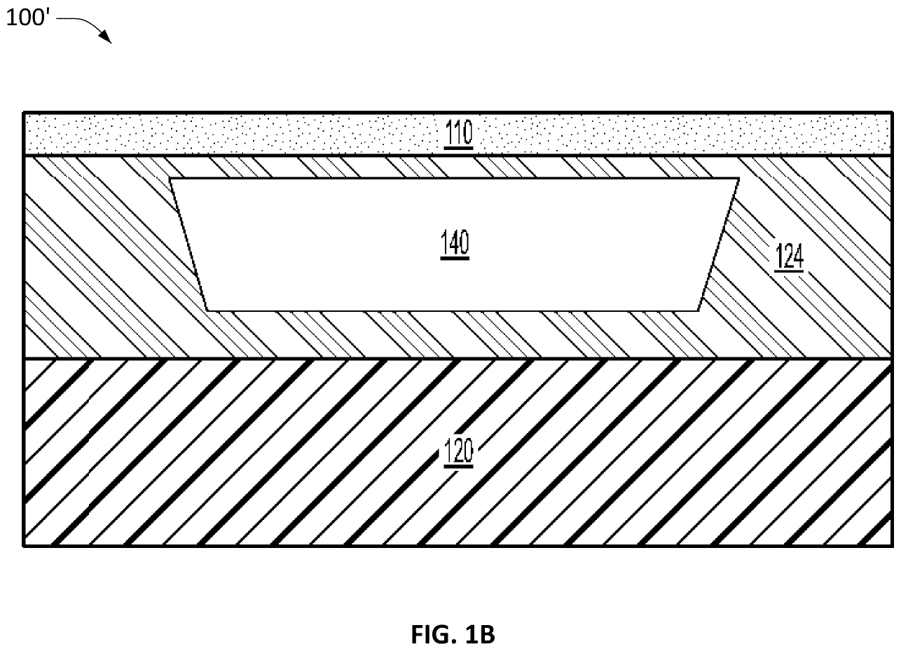

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

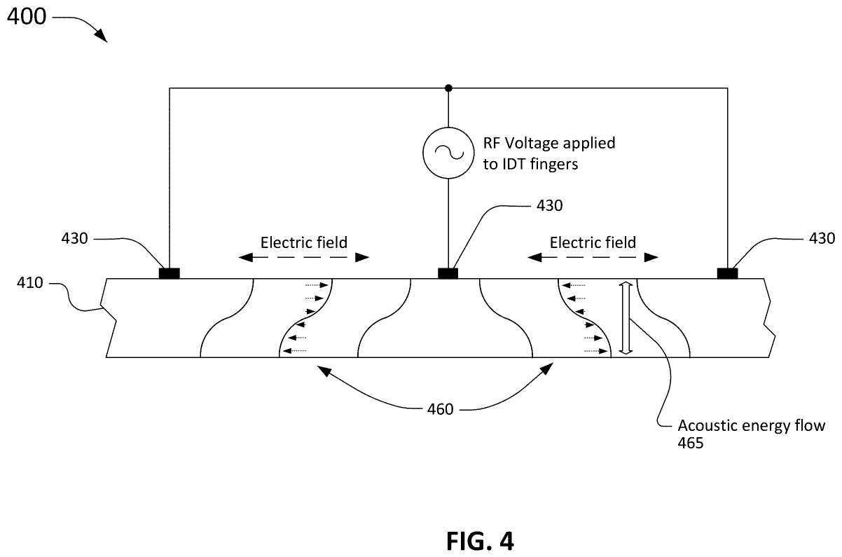

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

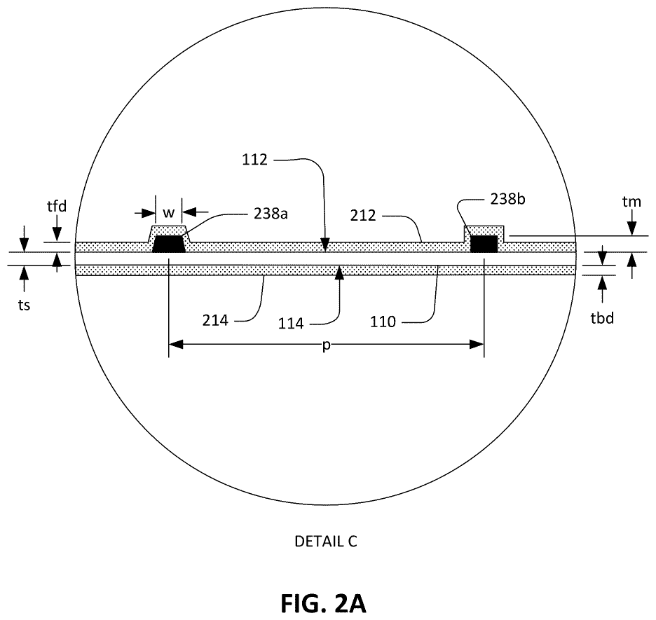

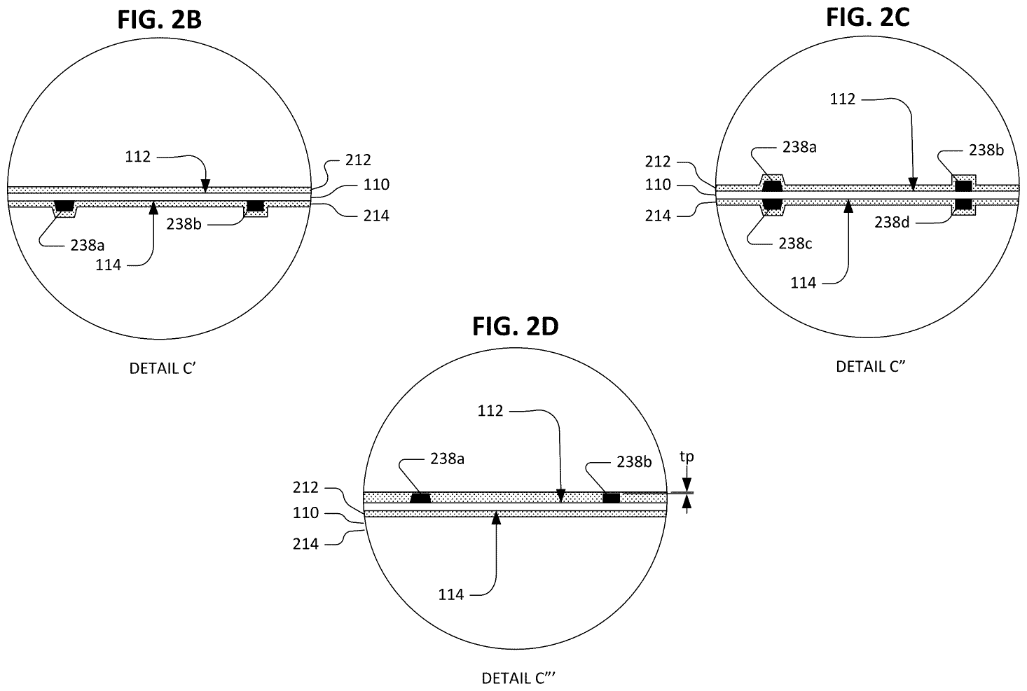

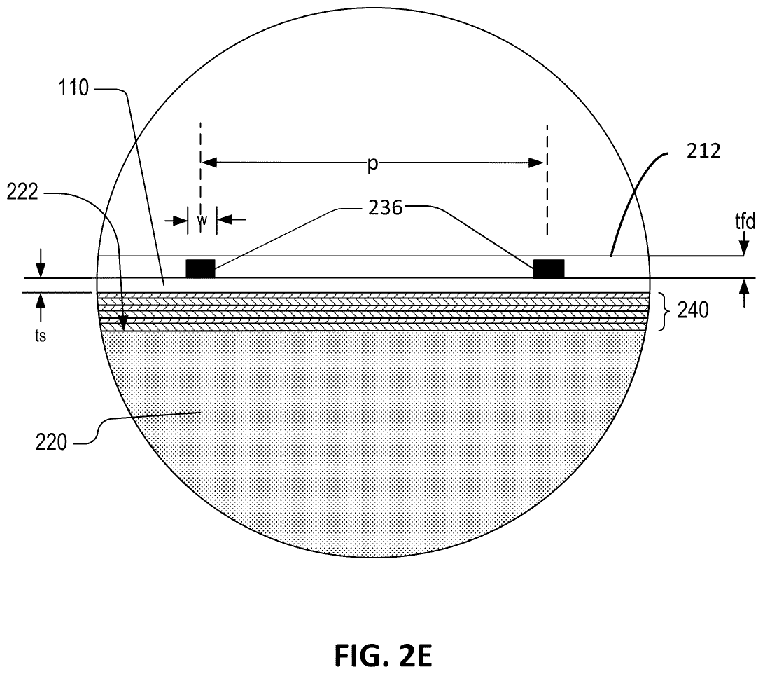

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar.

The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

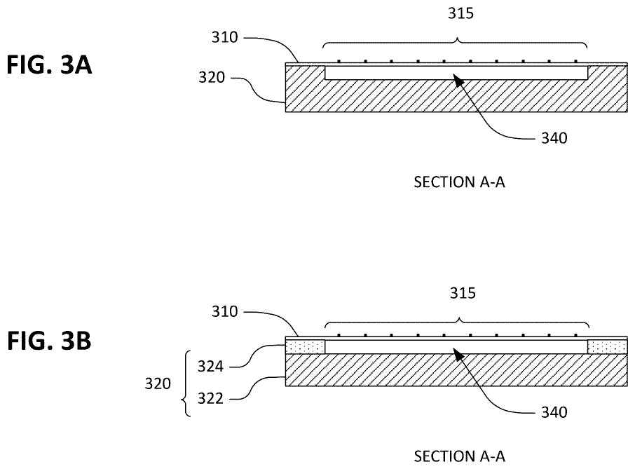

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

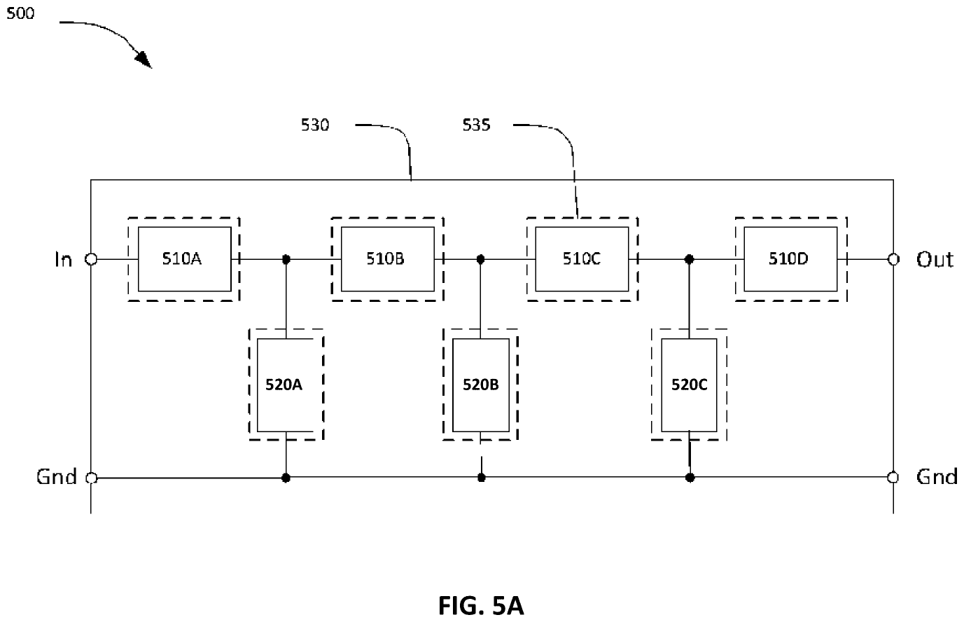

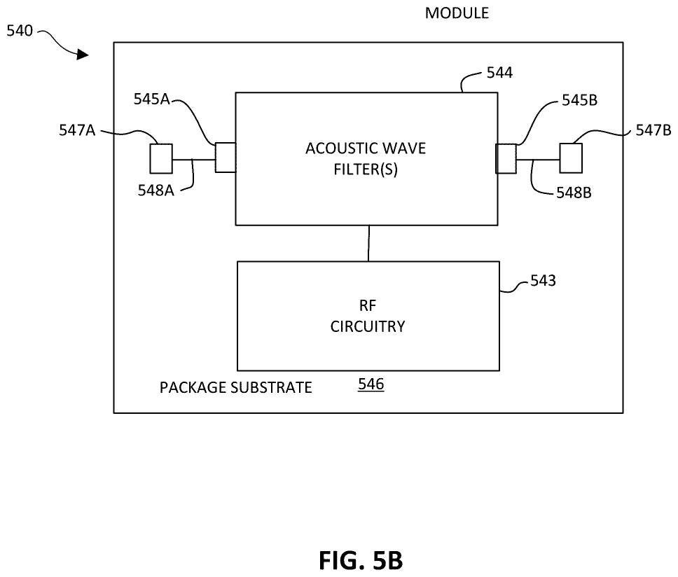

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. As discussed in more detail below, filter 500 may also contain additional reactive components, such as inductors (not shown in FIG. 5A).

The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as the shunt resonators 520A, 520B, and 520C are each connected from nodes between adjacent series resonators to a ground connection. For example, shunt resonator 520A is connected between the ground connection and a node between adjacent series resonators 510A and 510B. Moreover, a filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

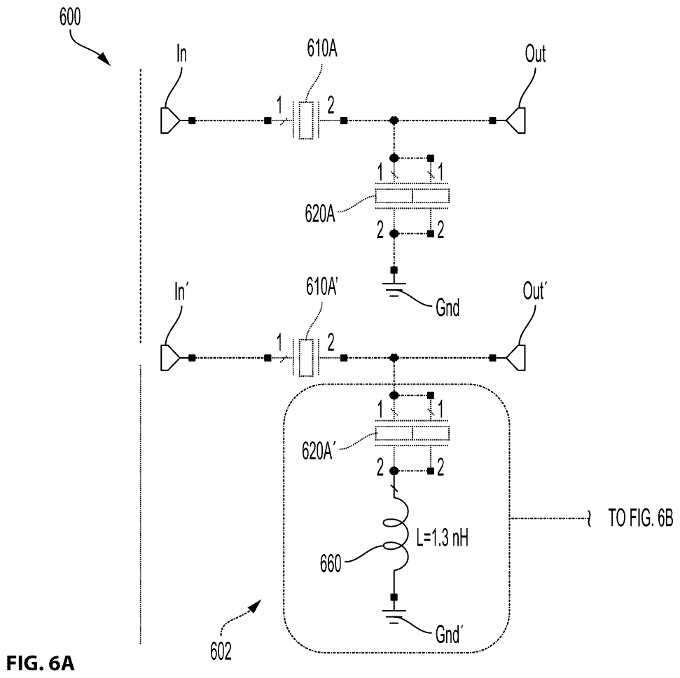

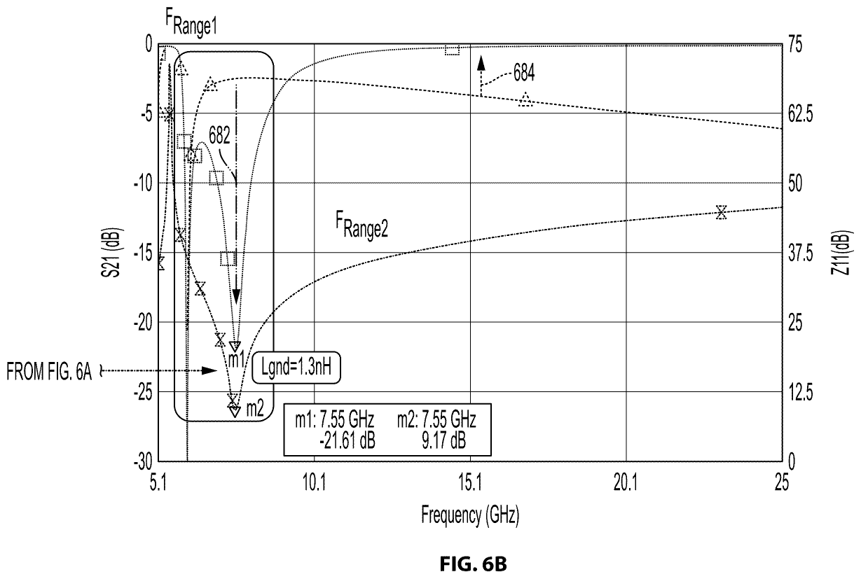

As described above, RF filters, such as filter 500, can be configured to use a ground inductance in series with a shunt resonator to create a transmission zero (Tz) at a desired frequency to improve rejections of the frequency response. FIG. 6A illustrates a circuit diagram of a filter (or partial filter) using resonators with a ground inductance in series according to an exemplary aspect.

As shown, FIG. 6A illustrates a schematic circuit diagram and layout for filters 600 and 602 using resonators, for example, XBARs, such as the general XBAR configuration 100 described above, for example. The filters 600 and 602 have a filter architecture including a series resonator 610A and 610A′, respectively, and a shunt resonators 620A and 620A′, respectively. The shunt resonators 620A and 620A′ each include at least two shunt resonators (e.g., a pair of shunt resonators or at least two shunt sub-resonators) in parallel. The series resonator 610A and 610A′ are connected in series between a first port and a second port, which can be an input and an output of the filters 600 and 602, for example. That is, in FIG. 6A, the first and second ports are labeled “In”, “In” and “Out”, “Out′”, for 600 and 602, respectively. However, the filters 600 and 602 are bidirectional and either port may serve as the input or output of the filter. The shunt resonator 610A and 610A′ are connected from nodes between the series resonators to ground. The In and Out ports can correspond to those described above with respect to FIG. 5A if the filters 600 and/or 602 are implemented in a ladder filter architecture as described above.

As further shown and described below, filter 602 contains an additional reactive component, i.e., inductor 660. In either case, the shunt resonator and the series resonator may be XBARs. The inclusion of one series and two shunt resonators in filters 600 and 602 is an example. A filter may have more or fewer than three total resonators, more or fewer than one series resonator, and more or fewer than two shunt resonators according to various ladder filter architectures as would be appreciated to on skilled in the art. Typically, all of the series resonators are connected in series between an input and an output of the filter. All of the shunt resonators are typically connected between ground and the input, the output, or a node between two adjacent series resonators.

As generally described above, filter devices, such as filters 600 and 602, are configured to pass signals at certain frequencies (or frequency bands) and to stop signals at other frequencies (or frequency bands). FIG. 6B is an exemplary graph of filter responses of the circuit diagram shown in FIG. 6A according to an exemplary aspect. More particularly, FIG. 6B shows the admittance in dB as a function of frequency for the filters 600 and 602, which is simulated using finite element method (FEM) simulation techniques.

As illustrated therein, filter 600 has a stopband, used interchangeably herein as a rejection, within F_{Range1}, but filter 600 does not have an efficient rejection in F_{Range2} as shown in by the dashed line annotated by a “A”. To improve rejection of the filter 600, a ground inductor 660 can be added in series with shunt resonator 620A′. By doing so, filter 602 is shown by the dashed line annotated by a “” in FIG. 6B to have an improved stopband within F_{Range1} when compared to filter 600. That is, arrow 682 indicates the improved response (i.e., steeper edge with lower admittance) between filter 600 and 602 in the F_{Range1}. In the exemplary aspect, as shown at m1, the admittance is −21.61 dB at a frequency of 7.55 GHz, which is in the first frequency range F_{Range1}. However, the tradeoff is that filter 602 has a less efficient rejection in F_{Range2} when compared to filter 600. For example, arrow 684 indicates the decreased response between filter 600 and 602 in the frequency range F_{Range2}. This admittance in the frequency range F_{Range2} can be considered flyback and can lead to the incorrect passing of unwanted high-frequency signals that are otherwise intended to be blocked from passing through the filter 602.

Thus, according to this aspect, adding inductor 660 in series to a shunt resonator 620A′ shifts the resonance of the filter to a lower frequency while keeping the same anti-resonance, effectively increasing the coupling of the resonator, but has the tradeoff of the flyback. That is, the placement of the inductor 660 in series with the shunt resonator 620A′ for filter 602 provides for improved performance in the first frequency range F_{Range1}, but also creates the “flyback” or degradation of the filter in the second frequency F_{Range2}, which consequently reduces the overall performance of the filter 602 when compared to filter 600. In other words, a tuned inductor with the shunt resonator 620A′ will create a transmission zero (T_{z}) at the desired frequency to improve rejections, but inductor 660 creates a flyback at higher frequencies leading to lower rejection of certain data signals in that high frequency range.

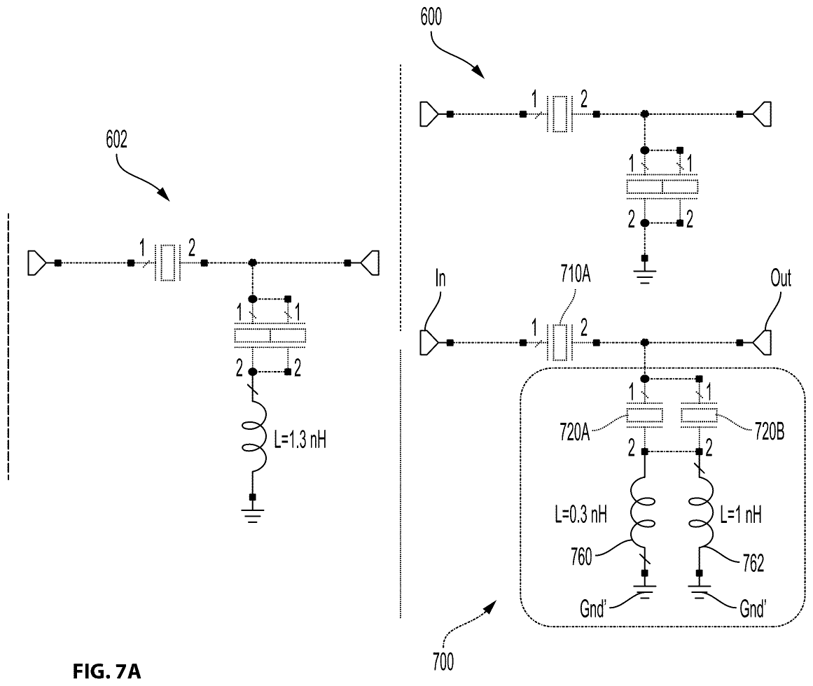

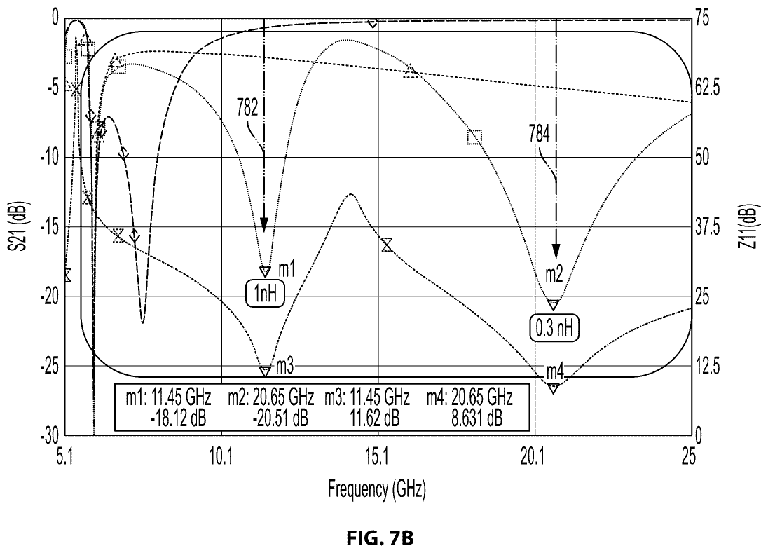

In view of the limitations of the filter 602 shown in FIG. 6A, the exemplary aspects provide for a filter with improved wideband rejection while reducing flyback in the high frequency range. In particular, FIG. 7A is a circuit diagram of a filter implementing resonators having a staggered inductor configuration according to an exemplary aspect. FIG. 7B is an exemplary graph of filter responses of the circuit diagram shown in FIG. 7A according to an exemplary aspect.

In general, FIG. 7A illustrates the same filter 600 as described above with respect to FIG. 6A and, as such, the details of filter 600 will not be repeated herein. However, FIG. 7A illustrates a schematic circuit diagram and layout for a filter 700 using XBAR resonators (e.g., the XBAR configuration 100) according to an exemplary aspect. In particular, the filter 700 has a filter architecture including a series resonator 710A, and shunt resonators 720A and 720B (e.g., a pair of shunt resonator or a pair of shunt sub-resonators). The series resonator 710A is connected in series between a first port and a second port. Again, FIG. 7A illustrates the first and second ports that are labeled as “In”, “In'” and “Out”, “Out'”, for filter 700. However, the filter 700 is bidirectional and either port may serve as the input or output of the filter. The shunt resonators 720A and 720B are connected in parallel from nodes between the series resonators to ground. According to an exemplary aspect, this filter shown in FIG. 7A can be implemented according to a similar ladder filter configuration as described above with respect to FIG. 5A, for example.

According to the exemplary aspect, the filter 700 includes a pair of inductors 760 and 762 that are coupled in parallel to each other. It is again noted that the inclusion of one series (e.g., resonator 710A) and two shunt resonators (e.g., resonators 720A and 720B) in filter 700 are an example. A filter (e.g., a ladder filter configuration) may have more or fewer than three total resonators, more or fewer than one series resonator, and more or fewer than one two resonators. Typically, all of the series resonators are connected in series between an input and an output of the filter. All of the shunt resonators are typically connected between ground and the input, the output, or a node between two adjacent series resonators. Each of the resonators of filter 700 can be implemented with any of the XBAR resonators shown and described above with respect to FIGS. 1A-1B, 2A-2E and 3A-3B, for example.

According to the exemplary embodiment, filter 700 implements different inductors on each one of the ground branches of the shunt resonators, i.e., shunt resonators 720A and 720B. Through the use of inductors 760 and 762, multiple tunable frequencies T_{zs} can be generated. According to an exemplary aspect, the filter 700 as a ground inductance 1.3 nH that is effectively split into separate inductances (e.g., 0.3 nH and 1.0 nH) for inductors 760 and 762, respectively, that are connected to each branch of the shunt resonators 720A and 720B, respectively.

Thus, according to the exemplary aspect, a filter 700 is provided that includes one or more series resonators (e.g., 710A) connected between a pair of ports (e.g., “IN” and “OUT” ports), a plurality of shunt resonators (e.g., 720A and 720B) connected between a ground connection and a node between the at least one series resonator and one of the pair of ports; and a plurality of inductors (e.g., 760 and 762) that are connected in parallel to each other and between the ground connection and the plurality of shunt resonators (e.g., 720A and 720B), respectively. Moreover, at least two or more inductors of the plurality of inductors have staggered inductance values that are different from each other, such that the plurality of inductors are configured to reduce the flyback effect in the high frequency range. As described above and in an exemplary aspect, each of the series resonator and the shunt resonators includes a substrate, at least one piezoelectric layer attached either directly or via one or more intermediate layers to the substrate, and an interdigital transducer (IDT) at the at least one piezoelectric layer and including a plurality of interleaved IDT fingers extending from first and second busbars respectively.

As further noted above, FIG. 7B is an exemplary graph of filter responses of the circuit diagram shown in FIG. 7A according to an exemplary aspect. More particularly, FIG. 7B shows the admittance in dB as a function of frequency for the filters 600 and 700, which is simulated using finite element method (FEM) simulation techniques.

In general, filters 600 and 700 are configured to pass signals at certain frequencies and to stop signals at other frequencies as generally described above. By adding the staggered ground inductances 760 and 762 to resonators 720A and 720B, filter 700 obtains an improved wideband rejection in first frequency range F_{Range1}. However, this configuration also addresses the “flyback” effect otherwise encountered by filter 602 as described above and shown in FIG. 6B. In particular, arrow 782 indicates the improved response and rejection between filter 600 and 700. As shown at m1, the admittance is −18.12 dB at a frequency of 11.45 GHz, which is in the second frequency range F_{Range2}.

Additionally, filter 700 has a second rejection when compared to filter 600. For example, arrow 784 indicates the increased response of filter 700 as illustrated by the dotted line annotated by “□” of filter 700 compared with the frequency response of filter 600 illustrated by the dotted line annotated by “Δ”. For reference, the frequency of filter 602 is shown as a dotted line annotated by “⋄”.

In particular, as shown at m2, the admittance is −20.51 dB at a frequency of 20.65 GHZ, which is also in this higher second frequency range F_{Range2}. Thus, the staggered inductor configuration of filter 700 reduces the flyback as illustrated in FIG. 7B by creating these additional rejection frequency ranges. The specific frequency response of the pair of shunt resonators 720A and 720B with staggered inductors 760 and 762, respectively, is shown to have an anti-resonance peak at 11.45 GHZ (identified as m3) and 20.65 GHZ (identified as m4). Effectively, this configuration pulls the overall frequency response of filter 700 (illustrated by the dotted line annotated by “□”) downward at points m1 and m2. Effectively, the staggered ground inductors 760 and 762 having staggered inductance values can also be implemented in such high frequency filters for, for example, spurious suppression in the S2 mode, A3 mode, for example, and improve rejections in Wi-Fi 6 GHz region. According to an exemplary aspect, the use staggered ground inductors 760 and 762 improve rejections near targeted high frequencies, for example, 28 GHz.

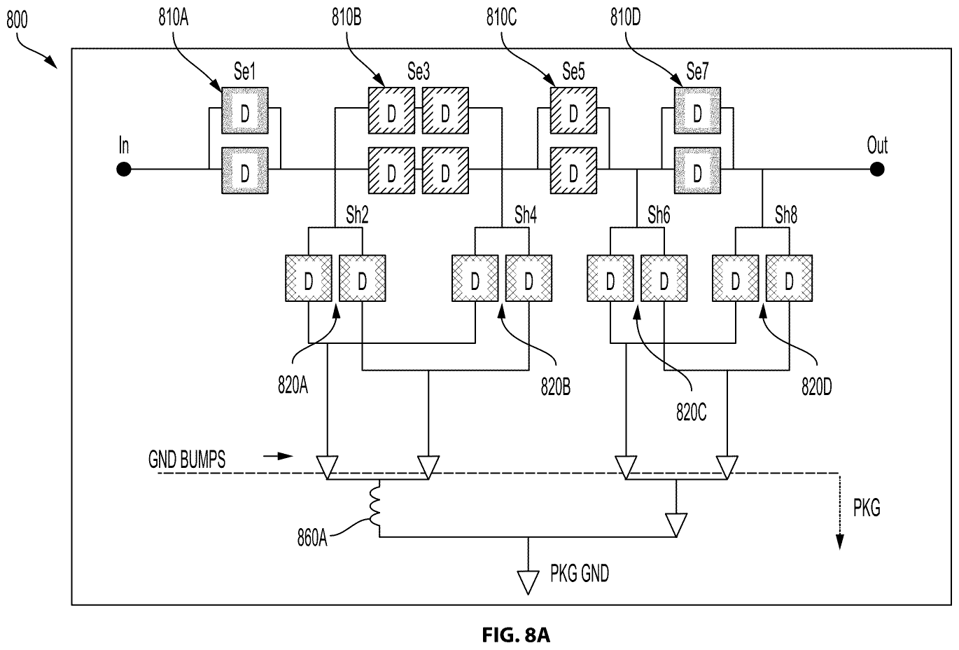

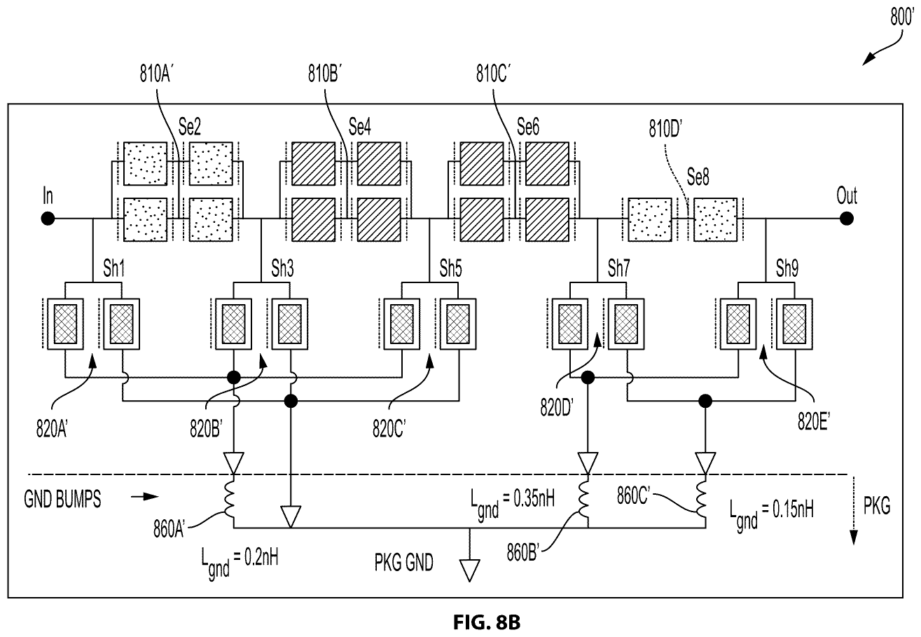

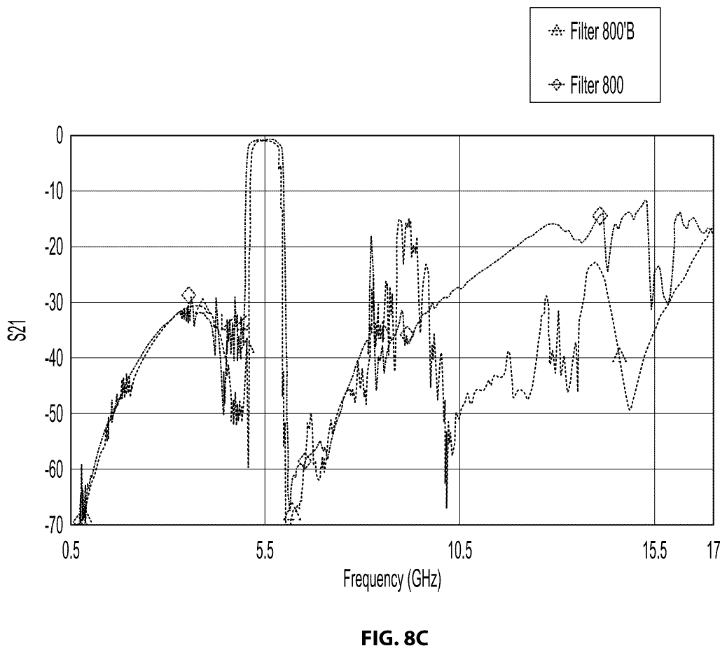

FIG. 8A and FIG. 8B are exemplary layouts incorporating aspects of the filters with reference to FIG. 6A and FIG. 7A. In particular, FIG. 8A is an exemplary layout of a filter 800 according to an exemplary aspect. Moreover, FIG. 8B an exemplary layout of a filter 800′ having a staggered inductor configuration incorporating exemplary aspects of the present disclosure.

As generally shown, both filters 800 and 800′ have a filter architecture including four series resonators 810A (e.g., Se1), 810B (e.g., Se3), 810C (e.g., Se5), 810D (e.g., Se7), and 810A′ (e.g., Se2), 810B′ (e.g., Se4), 810C′ (e.g., Se6), 810D′ (e.g., Se8), respectively. Moreover, filter 800 includes four shunt resonators 820A (e.g., Sh2), 820B (e.g., Sh4), 820C (e.g., Sh6) and 820D (e.g., Sh8). Filter 800′ includes five shunt resonators 820A′ (e.g., Sh1), 820B′ (e.g., Sh3), 820C′ (e.g., Sh5), 820D′ (e.g., Sh7) and 820E′ (e.g., Sh9). It should be appreciated that the filter configurations shown in FIGS. 8A and 8B are similar the resonator layout shown in FIG. 5A and can be implemented with any combination of resonators having the configurations shown in FIGS. 1A-1B, 2A-2E, and 3A-3B, for example.

Moreover, similar to the configurations described above, the series resonators of both filter 800 and 800′ are connected in series between a first port and a second port. Again, in FIG. 8A and FIG. 8B, the first and second ports are labeled “In” and “Out”, respectively. Moreover, the shunt resonators 820A, 820B, 820C, 820D of filter 800 and the shunt resonators 820A′, 820B′, 820C′, 820D′ and 820E′ of filter 800′ are connected from nodes between pairs of adjacent series resonators and ground.

According to the exemplary aspects, FIG. 8A and 8B are schematic circuit diagrams and layouts for filters 800 and 800′, which can be implemented using XBARs, such as the general XBAR configuration 100 described above, for example. It should be appreciated that the inclusion of the number of series and shunt resonators is an example. In particular, each of filters 800 and 800′ can have more or fewer total resonators, for example, more or fewer than four series resonators, and more or fewer than four/five shunt resonators. In addition, each of the resonators may be split into two or more sub-resonators in an exemplary aspect. For example, the sub-resonators in FIG. 8A are labeled as “D” and the resonators in FIG. 8B can have a similar configuration. A resonator that comprises a pair of (or more) sub-resonators typically has the same configurations as each other, including the same aperture, approximately the same length and the same stack. Dividing an acoustic resonator into multiple sub-resonators has a primary benefit of reducing the peak stress that would occur if each acoustic resonator had a single large diaphragm.

In the exemplary filters 800 and 800′, the series resonators 810A, 810B, 810C, and 810D and 810A′, 810B′, 810C′, and 810D′ and the shunt resonators 820A, 820B, 820C, and 820D and the shunt resonators 820A′, 820B′, 820C′, 820D and 820E′ of the filters 800 and 800′, respectively, are formed on at least one, and in some cases a single, layer of piezoelectric material bonded to a silicon substrate (not visible). As also described above, each resonator includes a respective IDT (not shown).

In one aspect of the disclosure, each output of the shunt resonators 820A, 820B, 820C, and 820D and 820A′, 820B′, 820C′, 820D and 820E′ of the filters 800 and 800′, respectively, are each connected to their own respective ground bumps. However, as shown in FIG. 8A, a single inductor 860A is disposed between each pair of sub-resonators of shunt resonators 820A and 820B and ground. This configuration is similar to that of filter 602 as described above with respect to FIG. 6A.

In contrast, FIG. 8B illustrates a filter 800′ with a staggered inductor configuration according to an exemplary aspect. In particular, filter 800′ includes three inductors 860A′, 860B′ and 860C′ that are each connected in series between the ground connect (e.g., “PKG GND”) and one or more sub-resonator of one or more shunt resonators, such as resonators 820A′ to 820E′. It is noted that the induction values (H) as annotated in FIG. 8B, are provided merely for exemplary purposes only, and that the value of these inductors 860A′, 860B′ and 860C′ can be configured based on a preferred optimization of the filter 800′ as would be appreciated to one skilled in the art. For example, the induction values are desired to be as low as possible in a configuration in order to obtain Tz values in the higher frequencies. According to the exemplary aspect, the staggered inductor configuration using inductors 860A′, 860B′ and 860C′ that are each coupled to one or more separate shunt resonators and ground provides for improved wideband rejection while reducing the flyback effect as described above with respect to FIG. 7B, for example.

As described above, each exemplary filter shown in FIGS. 6A, 7A, 8A and 8B includes a plurality of resonators where one or more of the respective of resonators (e.g., shunt and/or series resonators) can be split into two or more separate sub-resonators. For example, filter 800′ illustrates each of shunt resonators 820A′ to 820E′ formed of a pair of sub-resonators, each with a first sub-resonator coupled to a ground inductor and a second sub-resonator connected directly to a ground connection. That is, the aspect of splitting the resonators to sub-resonators allows for each output of each respective resonator to be connected to a respective ground bump. In another aspect of the disclosure, the split/separate resonator outputs additionally allow for the placement of the staggered inductors, which provide for correction of the flyback and specific adjustment of Tz values, as described above.

FIG. 8C shows an exemplary graph of filter responses of filters 800 and 800′ described above with respect to FIGS. 8A and 8B according to an exemplary aspect. The frequency response of filter 800 is annotated by a “⋄” and the frequency response of filter 800′ is annotated by a “Δ” FIG. 8C provides a plot illustrating the admittance in dB as a function of frequency for the filters 800 and 800′, which is simulated using finite element method (FEM) simulation techniques.

As shown, the respective filters have a similar filter response in the first frequency range (e.g., F_{Range1} as described above), but filter 800′ has an improved frequency in the higher frequency range (e.g., the second frequency F_{Range2} as described above), which addresses the “flyback” or degradation of the filter in this higher frequency range as also described above. That is, in the higher frequency range F_{Range2}, the admittance dops significantly (i.e., in the negative admittance range) whereas the frequency response of filter 800 is closer to the passband in the first frequency range (F_{Range1}) and may impurely pass unwanted signals (e.g., signals otherwise outside the passband) through the filter. Thus, FIG. 8C illustrates that the staggered inductor configuration of filter 800′ provides for an over improved frequency response with wideband reduction compared to filter 800.

Referring back to FIG. 8B, and as described herein, the filter 800′ uses a split-ladder architecture in which the series resonators 810A′ to 810D′ can be fabricated on a first chip and the shunt resonators 820A′ to 820E′ can be fabricated on a second chip. The first chip and the second chip can then be mounted on a circuit board that provides interconnections between the first and second chips as described above with respect to FIG. 5A, for example.

In addition, the plurality of shunt resonators 820A′ to 820E′ have four ground contact pads labeled “GND BUMPS”. Inductors 860A′, 860B′ and 860C′ represent the conductor paths through the respective ground contact pads to the system ground (i.e., “PKG GND”). In the exemplary aspect, inductors 860A′, 860B′ and 860C′ can be parts of the second chip, but each inductor may include conductors on and off the second chip. For example, each inductor may include a conductor on the second chip, a conductive bump or ball connecting the second chip to the circuit board within the filter package, one or more conductors on the circuit board, and a conductive bump or ball connecting the package to a system ground plane according to various exemplary aspect.

Moreover, the filter 800′ includes four instances of “partial inductive cross-coupling” using the staggered ground inductors described herein. Partial inductive cross-coupling occurs when at least one sub-resonator of a first shunt resonator (e.g., one of the sub-resonators of 820A′) and at least one, but not all, sub-resonators of a second shunt resonator (e.g., one of the sub-resonators of 820B′ and 820C′) share the same ground contact pad, which helps reduce the overall size of the filter components on each respective ship. In the filter 800′, one of the sub-resonators of each of shunt resonators 820A′, 820B′ and 820C′ connect to system ground via inductor 860A′. The other of the sub-resonators of each of shunt resonators 820A′, 820B′ and 820C′ connect directly to system ground without any inductor. It should be appreciated that this straight connection to ground will still travel through the circuit board (e.g., PCB), which may show some parasitic inductance. However, this impedance value will be significantly lower than that of each of inductors 860A′, 860B′ and 860C′, which are configured to have staggered inductance values to eliminate or minimize the “flyback” effect at higher frequencies as discussed above.

Moreover, one of the sub-resonators of each of shunt resonators 820D′ and 820E′ connect to system ground via each inductor 860B′ and 860C′, respectively. As also described above, each inductor has a different inductance (i.e., they are “staggered”) of which the example inductances are 0.2 nH, 0.35 nH and 0.15 nH. As noted above, these inductances can be set in chip design to adjust the overall frequency response of filter 800′ according to an exemplary aspect.

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
at least one series resonator connected between a pair of ports;
a plurality of shunt resonators connected between a ground connection and a node between the at least one series resonator and one of the pair of ports; and
a plurality of inductors that are each connected in series between the ground connection and the plurality of shunt resonators, respectively,
wherein at least two of the plurality of inductors have staggered inductance values that are different from each other, and
wherein each of the at least one series resonator and the plurality of shunt resonators includes:
a substrate,
a piezoelectric layer attached either directly or via one or more intermediate layers to the substrate, and
an interdigital transducer (IDT) on a surface of the piezoelectric layer and including a plurality of interleaved IDT fingers extending from first and second busbars respectively.

2. The filter device of claim 1, wherein the plurality of inductors are connected in parallel to each other.

3. The filter device of claim 1, wherein the at least one series resonator comprises a plurality of series resonators connected in series between the pair of ports.

4. The filter device of claim 3, wherein each of the plurality of shunt resonators are coupled to a node between a pair of adjacent resonators of the plurality of series resonators or a node between one of the plurality of series resonators and one of the pair of ports.

5. The filter device according to claim 1, wherein the piezoelectric layer and the IDT of each of the series and shunt resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved fingers of the IDT.

6. The filter device according to claim 1, wherein the substrate of each of the respective resonators includes a base and an intermediate layer and the piezoelectric layer includes a portion that is over a cavity that extends at least partially in the intermediate layer of the substrate.

7. The filter device according to claim 6, wherein the surface of the piezoelectric layer on which the IDT is disposed faces the cavity.

8. The filter device according to claim 1, wherein at least one of the at least one series resonator and the plurality of shunt resonators further comprises a Bragg reflector disposed between the substrate and the piezoelectric layer.

9. The filter device according to claim 1, wherein each of the plurality of shunt resonators comprises at least two sub-resonators.

10. The filter device according to claim 9, wherein a first sub-resonator of each of the at least two sub-resonators is coupled to an inductor of the plurality of inductors and a second sub-resonator of each of the at least two sub-resonators is coupled directly to the ground connection.

11. A filter device comprising:
at least one series resonator connected between a pair of ports;
a plurality of shunt resonators connected between a ground connection and a node between the at least one series resonator and one of the pair of ports; and
a plurality of inductors that are each connected in series between the ground connection and the plurality of shunt resonators, respectively,
wherein at least two of the plurality of inductors have staggered inductance values that are different from each other,
wherein each of the at least one series resonator and the plurality of shunt resonators includes a piezoelectric layer and an interdigital transducer (IDT) on a surface of the piezoelectric layer, and
wherein the piezoelectric layer and the IDT of each of the series and shunt resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by interleaved fingers of the IDT.

12. The filter device according to claim 11, wherein each of the at least one series resonator and the plurality of shunt resonators further includes a substrate, and the piezoelectric layer is attached either directly or via one or more intermediate layers to the substrate.

13. The filter device of claim 11, wherein the plurality of inductors are connected in parallel to each other.

14. The filter device of claim 11,
wherein the at least one series resonator comprises a plurality of series resonators connected in series between the pair of ports, and
wherein each of the plurality of shunt resonators are coupled to a node between adjacent resonators of the plurality of series resonators or a node between one of the series resonators and one of the pair of ports.

15. The filter device according to claim 12, wherein the substrate of each of the respective resonators includes a base and an intermediate layer and the piezoelectric layer includes a portion that is over a cavity that extends at least partially in the intermediate layer of the substrate.

16. The filter device according to claim 15, wherein the surface of the piezoelectric layer on which the IDT is disposed faces the cavity.

17. The filter device according to claim 12, wherein at least one of the at least one series resonator and the plurality of shunt resonators further comprises a Bragg reflector disposed between the substrate and the piezoelectric layer.

18. The filter device according to claim 11, wherein each of the plurality of shunt resonators comprises at least two sub-resonators.

19. The filter device according to claim 18, wherein a first sub-resonator of each of the at least two sub-resonators is coupled to an inductor of the plurality of inductors, and a second sub-resonator of each of the at least two sub-resonators is coupled directly to the ground connection.

20. A radio frequency module comprising:
a filter device having at least one series resonator connected between a pair of ports, a plurality of shunt resonators connected between a ground connection and a node between the at least one series resonator and one of the pair of ports, and a plurality of inductors that are connected between the ground connection and the plurality of shunt resonators, respectively; and
a radio frequency circuit coupled to the filter device, the filter device and the radio frequency circuit being enclosed within a common package,
wherein at least two of the plurality of inductors have staggered inductance values that are different from each other,
wherein each of the at least one series resonator and the plurality of shunt resonators includes a piezoelectric layer and an interdigital transducer (IDT) on a surface of the piezoelectric layer, and
wherein the piezoelectric layer and the IDT of each of the respective resonators are configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by interleaved fingers of the IDT.
